(19) United States
(12) Patent Application Publication
(10) Pub. No.: US 2005/0195015 A1
(43) Pub. Date: Sep. 8, 2005

(54) Low voltage boosted analog transmission gate

(76) Inventor: Matthew Goldman, Folsom, CA (US)

Correspondence Address: INTEL CORPORATION, P.O. BOX 5326, SANTA CLARA, CA, 95056-5326, US

(21) Appl. No.: 10/794,894

(22) Filed: Mar. 5, 2004

(51) Int. Cl. G11C 8/00

(52) U.S. Cl. 327/391

(57) ABSTRACT

A drive boost circuit provides a boosted voltage potential for driving the gate of pass device. The drive boost circuit may be one or more stages and include an inverter pair where the first inverter is powered from an operating voltage while the second inverter receives the generated boosted voltage potential that is used to drive the gate of a pass transistor.

A conventional transmission gate in Complementary Metal Oxide Semiconductor (CMOS) circuits has parallel connected N-channel and P-channel devices. Today's portable communication products have reduced the supply voltage for CMOS circuits, which adversely affects the propagation delay of the transmission gates used to latch data and synchronize timing. What is needed is a circuit and method to reduce the impedance of the transmission gate as operating voltage potentials are decreased.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates features of the present invention for boosting the voltage potential supplied to an analog pass device that may be incorporated into a processor;

FIG. 2 illustrates one embodiment of a drive boost circuit and pass device in accordance with the present invention; and

FIG. 3 illustrates another embodiment of the drive boost circuit that provides a boosted gate drive for the pass device in accordance with the present invention.

It will be appreciated that for simplicity and clarity of illustration, elements illustrated in the figures have not necessarily been drawn to scale. For example, the dimensions of some of the elements may be exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

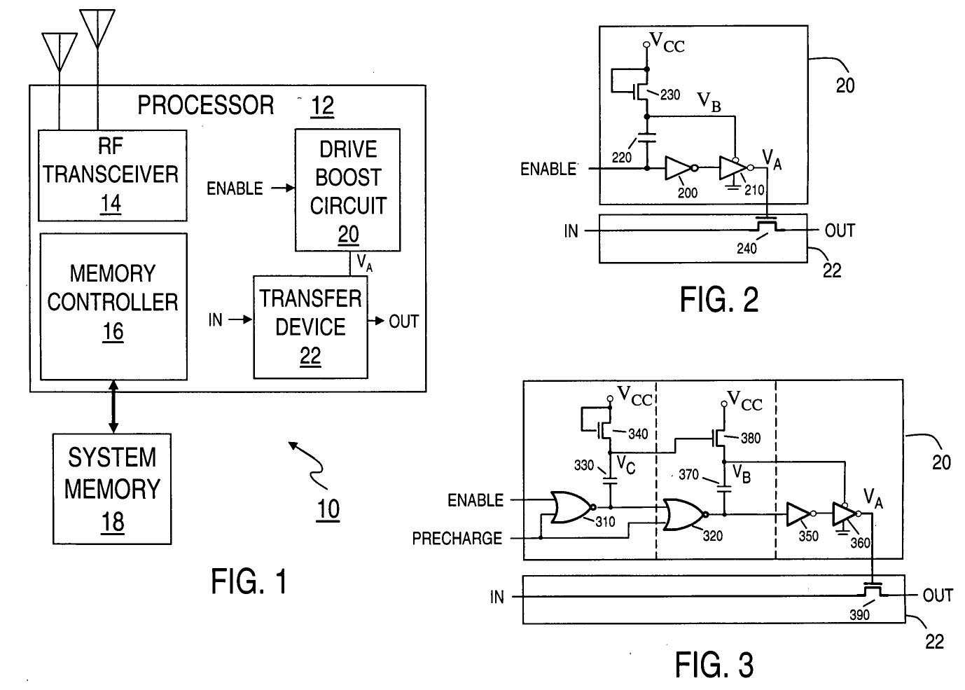

FIG. 1 illustrates features of the present invention that may be incorporated, for example, into a wireless communications device 10, although the claimed subject matter of the present invention may be incorporated into other applications. In the wireless communications embodiment, a transceiver 14 both receives and transmits a modulated signal from one or more antennas. The analog front end transceiver may be a stand-alone Radio Frequency (RF) integrated analog circuit, or alternatively, be embedded with a processor 12 as a mixed-mode integrated circuit. The received modulated signal is frequency down-converted, filtered, then converted to a baseband, digital signal. Processor 12 may include baseband and applications processing functions, and in general, be capable of fetching instructions, generating decodes, finding operands, performing the appropriate actions and storing results. The digital data processed by processor 12 may be transferred, under the control of a memory controller 16, across an interface for storage by a system memory 18. Processor 12 further includes a drive boost circuit 20 in combination with a transfer device 22. Drive boost circuit 20 generates the boosted gate voltage used to drive transfer device 22.

Embodiments of the present invention for generating a boosted gate potential supplied to the gate of a pass device may be used in a variety of applications such as general-purpose microprocessors, Digital Signal Processors (DSPs), Reduced Instruction-Set Computing (RISC), Complex Instruction-Set Computing (CISC) and Flash memory device, among other electronic components. In particular, the present invention may be used in smart phones, communicators and Personal Digital Assistants (PDAs), medical or biotech equipment, automotive safety and protective equipment, and automotive infotainment products. However, it should be understood that the scope of the present invention is not limited to these examples.

FIG. 2 illustrates one embodiment of drive boost circuit 20 that provides a boosted voltage potential for driving the gate of transfer device 22 in accordance with the present invention. Drive boost circuit 20 includes an inverter pair formed by inverters 200 and 210, where inverter 200 receives an ENABLE signal and inverter 210 generates the boosted drive potential VA. Although not explicitly shown in the figure, inverter 200 is connected to power conductors for receiving a positive operating potential V_{CC} and a ground potential. However, inverter 210 is not similarly connected to those same power conductors, but rather, is connected to receive a positive operating potential VB and the ground potential.

The positive operating potential VB is supplied from a node formed by a common connection of a first terminal of a capacitor 220 and a source of N-channel device 230. The second terminal of capacitor 220 is connected to the input of inverter 200 while the drain and gate of device 230 are commonly connected to the power conductor that receives the positive operating potential VCC. The source of the diode-connected device 230 is connected to inverter 210 to provide the potential VB. Although device 230 is shown and described as a diode-connected device, one skilled in the art would recognize other types of devices that may be used to provide a precharge voltage potential to a terminal of capacitor 220. The output of inverter 210 is connected to the gate of pass device 240, with the source of device 240 receiving the signal IN and the drain providing the signal OUT.

Although FIG. 2 illustrates a circuit that may be used to generate the boosted gate voltage VA that is necessary to drive an nMOS pass gate (device 240), it is understood that a complementary scheme may be implemented to generate a negative voltage for use with a pMOS pass gate. Also note that capacitor 220 may be processed as having conductive plates separated by a dielectric material, or alternatively, may be implemented as an nMOS device in inversion or as a pMOS device in accumulation. In operation, storage capacitor 220 is precharged when pass device 240 is disabled. The signal ENABLE may then transition from a logic low value to a logic high value, which boosts the voltage potential VB to approximately 2V_{CC}. The boosted voltage potential VB also causes the voltage potential VA to be boosted above V_{CC}. Note that the actual voltage potential VA supplied to the gate of pass device 240 is the result of the capacitor divider between the storage cap shown and the load capacitance on the gate of device 240.

FIG. 3 illustrates another embodiment of drive boost circuit 20 that interfaces with transfer device 22 to provide a boosted gate drive potential in accordance with the present invention. If the capacitive load is large and the storage capacitor does not have enough time to recover to V_{CC} when the pass gate is disabled, then a second stage may be incorporated. This embodiment shows a two stage boosted pass gate having a first stage NOR gate 310 that receives an ENABLE signal and a PRECHARGE signal. A capacitor 330 in the first stage has one terminal connected to the output of NOR gate 310 and the other terminal connected to the source of a device 340. The gate and drain of device 340 are commonly connected to a power conductor to receive an operating voltage of V_{CC}.

The output of NOR gate 310 is connected to an input of the second stage NOR gate 320, with the other input of the NOR gate 320 also receiving the PRECHARGE signal. A capacitor 370 in the second stage has one terminal connected to the output of NOR gate 320 and the other terminal connected to the source of a device 380. The gate of device 380 is connected to the source of device 340 that generates the voltage potential VC. The drain of device 380 is connected to a power conductor that receives the operating voltage V_{CC}.

A pair of inverters are used to generate the boosted output that drives the gate of the pass device. The first inverter, i.e., inverter 350, has an input connected to the output of NOR gate 320. Inverter 350 receives power by connections to a positive operating potential V_{CC} and a ground potential. An output of inverter 350 is connected to an input of an inverter 360. Inverter 360 receives power by connections to a positive potential V_{B} and the ground potential. The output of inverter 360 is connected to the gate of pass device 390, with the source of device 390 receiving the signal IN and the drain providing the signal OUT.

In operation, the two stage embodiment allows both of the storage capacitors, i.e., capacitors 330 and 370, to be precharged to the voltage potential V_{cc} prior to enabling drive boost circuit 20. With the PRECHARGE signal asserted, both storage capacitors are precharged to a V_{CC} potential. Once the precharge is complete, the PRECHARGE signal may be disabled and drive boost circuit 20 allowed to operate under the control of the ENABLE signal. The first stage provides a boosted gate voltage V_{C} at the gate of charging device 380. By providing a higher gate voltage to device 380, the second stage storage capacitor 370 may be recharged more quickly. Since the capacitive load on the first stage is smaller than the load on the second stage, the capacitor divider that created the need for a two stage design may be minimized for the first stage.

It should be pointed out that transfer device 22, e.g. pass device 240 in FIG. 2 and pass device 390 in FIG. 3, is shown as a positively boosted nMOS pass device. Alternatively, transfer device 22 may be a negatively boosted pMOS pass device or a combination that includes both an nMOS and pMOS pass device. Drive boost circuit 20 that includes one or more stages to generate a boosted gate drive to the transfer device improves the performance of data transfers.

By now it should be apparent that the present invention enhances pass devices, even when circuitry operates at low operating voltages. By appropriately boosting the gate drive of the pass device as provided in the present invention, it is no longer necessary to use both an N-channel and P-channel devices as found in prior art circuitry. The minimum amount of boosting necessary to allow for elimination of one of the complimentary pair of pass devices is that voltage which results in the desired maximum resistance when the drive voltage is at the rail. With the proposed embodiments for drive boost circuit 20, circuits may operate at low voltages and selectively pass any voltage between the supply rails.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A circuit having a pass transistor, comprising:
a capacitor;
a first inverter and a terminal of the capacitor to receive an enable signal that boosts a charge stored on the capacitor to a voltage potential higher than an operating voltage of the first inverter; and
a second inverter coupled to the first inverter to generate an output signal to drive a gate of the pass transistor, where the second inverter receives power from the voltage potential stored at another terminal of the capacitor.

2. The circuit of claim 1 wherein the enable signal at a first level conditions the charge stored on the capacitor and at a second level boosts the charge on the capacitor to the voltage potential that is higher than the operating voltage.

3. The circuit of claim 1 further including a diode connected device having a gate and drain to receive the operating voltage and a source coupled to a terminal of the capacitor to provide the voltage potential.

4. The circuit of claim 3 wherein the diode connected device is an N-channel Metal Oxide Semiconductor (MOS) transistor.

5. A circuit, comprising:
a first inverter to receive an enable signal and generate a complemented enable signal, the first inverter to operate from an operating potential and a ground potential; and
a second inverter having an input to receive the complemented enable signal and operate from a boosted voltage potential that is different from the operating potential of the first inverter and supply an output signal having an amplitude greater than an amplitude of the enable signal.

6. The circuit of claim 5 further including a capacitor having a first terminal connected to an input of the first inverter and a second terminal connected to the second inverter to supply the boosted voltage potential.

7. The circuit of claim 5 further including a transistor having a gate and drain to receive the operating potential and a source coupled to the second terminal of the capacitor.

8. The circuit of claim 5 further including a pass transistor having a gate coupled to an output of the second inverter, a source to receive an input signal and a drain to provide an output signal.

9. A circuit, comprising:
a first stage to receive a precharge signal and an enable signal and generate a first boosted signal;
a second stage to receive the precharge signal and the first boosted signal and generate a second boosted signal, where the first and second boosted signals have amplitudes greater than an amplitude of the enable signal; and
a serially connected inverter pair where a first inverter has an input coupled to an output of the second stage and a second inverter receives power from the second boosted signal to generate an output signal.

10. The circuit of claim 9, wherein the first stage further includes:
a first capacitor; and
a first device having a gate connected to a drain, and further having a source coupled through the first capacitor to an output of the first stage.

11. The circuit of claim 10, wherein the second stage further includes:
a second capacitor; and
a second device having a gate connected to the source of the first device, and further having a source coupled through the second capacitor to an output of the second stage.

12. The circuit of claim 9, further including a pass transistor having a gate coupled to an output of the second inverter, a source to receive an input signal and a drain to provide an output signal.

13. A system, comprising:
first and second antennas;
a transceiver coupled to the first and second antennas; and
a processor coupled to the transceiver, wherein the processor includes a first inverter to receive an enable signal and a second inverter to generate an output signal having an amplitude greater than an amplitude of the enable signal.

14. The system of claim 13, further including:
a capacitor having a first terminal connected to an input of the first inverter and a second terminal connected to the second inverter to supply a boosted voltage potential; and
a transistor having a gate and drain to receive an operating voltage and a source coupled to the second terminal of the capacitor.

15. The system of claim 13, further including:
a first stage logic gate to receive an enable signal and a precharge signal and generate a first boosted signal; and
a second stage logic gate to receive the precharge signal and the first boosted signal and generate a second boosted signal, the second boosted signal to provide the second inverter with a boosted voltage potential.

16. The system of claim 13, further including:
a pass device having a control gate coupled to an output of the second inverter, a first current conducting terminal to receive an input signal and a second current conducting terminal to provide an output signal.

17. A method, comprising:
precharging a node;
transitioning an input signal from a low voltage level to a high voltage level to capacitively couple the node from a first voltage value to a boosted voltage potential;
complementing the input signal in a first inverter; and
using the complemented input signal at a second inverter and the boosted voltage potential to generate an output signal having an amplitude substantially at the boosted voltage potential.

18. The method of claim 17 further including:
driving a gate of a pass transistor with the output signal from the second inverter.

19. The method of claim 18 further including:
receiving a signal at a source of the pass transistor and passing the signal to a drain without amplitude loss.
